(19) United States
(12) Patent Application Publication
(10) Pub. No.: US 2013/0026922 A1
(43) Pub. Date: Jan. 31, 2013

(54) APPARATUS INCORPORATING AN OPTICALLY TRANSMITTING CIRCUIT BOARD

(71) Applicants: Steven C. Allen, Beverly, MA (US); Camil Ghiu, Danvers, MA (US)

(72) Inventors: Steven C. Allen, Beverly, MA (US); Camil Ghiu, Danvers, MA (US)

(73) Assignee: OSRAM SYLVANIA INC., Danvers, MA (US)

(21) Appl. No.: 13/194,537

(22) Filed: Jul. 29, 2011

(51) Int. Cl. H01J 7/24; H01L 33/60

(52) U.S. Cl. 315/113; 257/98; 257/E33.072

(57) ABSTRACT

An apparatus and method of a lamp including an optically transmitting, thermally conductive substrate is provided. The substrate has a first side, a second side, and at least one edge. At least one solid state light source, such as but not limited to a light emitting diode, is disposed on the first side of the substrate. The at least one solid state light source (e.g., light emitting diode) includes at least one junction having a first junction temperature. The substrate used is an optically transmitting, thermally conductive substrate, with a thermal conductivity greater than or equal to about 3 W/mK.

### STATEMENT OF GOVERNMENT INTEREST

This invention was made with U.S. Government support under DOE Cooperative Agreement No. DE-EE0000611, awarded by the U.S. Department of Energy. The U.S. Government may have certain rights in this invention.

### TECHNICAL FIELD

The present invention relates to lighting, and more specifically, to lamps and luminaires including solid state light sources.

### BACKGROUND

Due to increasing energy costs, interest has risen in energy efficient products, including lighting devices. As a result, a wide variety of high efficiency lighting devices have been developed, including electroluminescent devices, light emitting polymers, and solid state light sources, such as but not limited to light emitting diodes (“LED” or “LEDs”) and the like (OLED, PLED, etc.). Of these, LEDs are of particular interest due to their exceptionally high efficiency, long lifetime, and relatively low operating temperature. However, LEDs are “point sources” of light, and typically emit light over a lambertian (120° FWHM) or nearly lambertian (120±40° FWHM) radiation pattern. Although this characteristic may be useful in some instances, it is not ideal for certain lighting applications such as spotlighting.

In an attempt to improve the light emission angle and other characteristics of light emitted by an LED light source, lamps that couple one or more LEDs with various types of optics have been developed. Generally, the optic (e.g., a reflector) is used to redirect rays emitted by the LED light source in a desired fashion. For example, the optic may be configured to collimate rays emitted by the LED light source, resulting in a focused beam with increased center beam candle power (CBCP).

Like any light source, an LED produces heat that must be managed to maintain the operating characteristics of the lamp within a desired range. In typical LED lamps, wherein the LED is situated at the bottom of an optic, the LED is placed on a circuit board which is in direct contact with a heat dissipating structure (a “heat sink”). The circuit board conducts and spreads the heat from the LED to the heat sink, which in turn dissipates the heat to the surrounding environment. This allows the LED junction temperature to remain within a desired operating range.

### SUMMARY

LEDs in conventional LED lamps are typically placed at or near the base of the optic, i.e., with the LED facing into the entrance aperture of the optic. As a result, many of the rays emitted by the LED do not impinge upon the optic sidewalls and are not collimated before they exit the lamp via the exit aperture. To address this issue, longer optics have been employed to increase the number of rays emitted from the LED impinging on the optic sidewalls before exiting the lamp to achieve a more collimated beam. However, the use of a long optic may impact the overall design and usefulness of such lamps.

As an alternative to placing an LED light source at the base of an optic, some LED lamps have been configured such that the LED source is oriented inward to the base of the optic. One example of such a lamp is the LED spotlight marketed under the product name CREE LRP38 (hereafter, the “Cree lamp”). The CREE lamp includes a lamp body that supports an LED light source and a reflector. The LED light source is positioned such that faces inward to the reflector. This configuration ensures that nearly 100% of the rays emitted by the LED light source will impinge upon the reflector. The LED light source is placed inward to and near the aperture of the reflector. As a result, direct contact between the LED light source and a heat sink (e.g., the lamp body) is not possible. Thus, to remove heat generated by the LED light source, the CREE lamp employs a bridge, which contains a heat pipe that conducts heat from the LED light source to the lamp body.

While the bridge, such as used in the CREE lamp described above, is effective for transferring heat produced by the LED light source to the lamp body, it has at least three negative effects on the performance of the lamp. First, the bridge reduces the efficiency of the lamp, because it is a relatively thick and opaque structure that absorbs at least some of the rays emitted by the LED light source. Second, the bridge reduces the CBCP of the lamp because it redirects rays that are not absorbed and may obstruct collimated light from exiting the lamp. Third, the bridge impacts the appearance of both the lit lamp and the beam of light produced by the lamp. Specifically, the bridge is clearly visible when looking into the lamp, and introduces shadows and/or asymmetry in the near field (and potentially far field) of the beam of light projected by the lamp. In addition, bridge may be expensive to manufacture.

As an alternative to a bridge, some LED-based spotlights use either an opaque circuit board or wires soldered directly to the LED package. In the former case, the circuit board is generally formed from a metal substrate, polymer, or composite (e.g. FR-4) substrate with conductive copper circuit thereon. In the latter case, no circuit board is utilized and the LED may be mounted directly to the heat sink. Neither of these alternatives, however, satisfactorily address the problems associated with the bridge.

Embodiments described herein provide one or more benefits relative to LED lamps of the prior art. For example, the lamps according to embodiments described herein may be configured such that all or substantially all of the LED-emitted rays hit the reflector, which may result in superior beam control and high CBCP. In addition, the lamps described herein may use a reflector having a relatively shallow depth, thereby allowing more space to be devoted to electronics, a heat sink, or other components. Moreover, the LED light sources used in the lamps described herein may not be directly visible to the eye, and the lamps do not employ a “bridge,” such as the one described above. For these and other reasons, lamps, luminaires, and methods according to described embodiments may allow for the provision of elegant LED lighting solutions.

In an embodiment, there is provided an apparatus. The apparatus includes a substrate having a first side, a second side, and at least one edge. The apparatus also includes at least one light emitting diode (LED) disposed on the first side, the at least one LED comprising at least one junction having a first junction temperature. The substrate is an optically transmitting, thermally conductive substrate and the substrate has a thermal conductivity greater than or equal to about 3 W/mK.

In a related embodiment, the substrate may be configured such that the temperature drop between the at least one junction and the at least one edge is less than or equal to about 40° C. In another related embodiment, the substrate may have a thickness ranging from about 0.1 mm to about 6 mm. In a further related embodiment, the substrate may include at least one material selected from the group consisting of AlN, polycrystalline Al₂O₃, BaF₂, BeO, CaF₂, InGaN, LiF, LiNbO₃, LiTaO₃, NaF, MgF₂, MgO, quartz, sapphire, SiC, Y₂O₃, Y₃Al₅O₁₂, and ZrO₂.

In still another related embodiment, the substrate may have a thermal conductivity ranging from about 3.5 to about 400 W/mK. In yet another related embodiment, the first junction temperature may be less than or equal to about 125° C. In still yet another related embodiment, the apparatus may further include an optic, wherein the first side of the substrate faces the optic. In a further related embodiment, the optic may include an aperture, and the substrate and the at least one LED may be disposed at or within the aperture. In another further related embodiment, the optic may include a reflector.

In still yet another related embodiment, the apparatus may further include a heat sink, the heat sink including a base, an opening positioned substantially opposite to the base, and a cavity therebetween, wherein the substrate may be disposed within the cavity or across the opening such that the first side of the substrate faces the base. In a further related embodiment, the substrate may conduct heat from the at least one junction to the heat sink, and may be configured such that the temperature drop between the at least one junction and the heat sink is less than or equal to about 40° C.

In another embodiment, there is provided an apparatus. The apparatus includes a heat sink having a base, an opening, and a cavity therebetween; an optically transmitting, thermally conductive substrate supported within the cavity or across the opening, the substrate comprising a first side, a second side, and at least one edge, the first side facing the base; at least one light emitting diode (LED) disposed on the first side of the substrate, the at least one LED comprising at least one junction having a first junction temperature; and wherein the substrate has a thermal conductivity greater than or equal to about 3 W/mK.

In a related embodiment, the apparatus may further include an optic positioned within the cavity and between the at least one LED and the base. In a further related embodiment, the at least one LED may emit rays, and at least a portion of the rays may be reflected by the optic through the substrate.

In another related embodiment, the substrate may be configured to conduct heat produced by the at least one LED to the heat sink, the substrate being configured such that the temperature drop between said at least one junction and said heat sink is less than or equal to about 40° C. In yet another related embodiment, the first junction temperature may be less than or equal to about 125° C. In still another related embodiment, the substrate may have a thermal conductivity ranging from about 3.5 to about 400 W/mK.

In another embodiment, there is provided a method. The method includes: providing a lamp, the lamp including an optically transmitting, thermally conductive substrate comprising a first side, a second side, and at least one edge, and at least one light emitting diode (LED) disposed on the first side, the at least one LED comprising at least one junction having a first junction temperature; emitting heat and radiation within a waveband from the at least one LED; causing at least a portion of the radiation within the waveband to pass through the substrate; and conducting, via the substrate, the heat emitted by the at least one LED from the junction to the at least one edge; wherein the substrate has a thermal conductivity greater than or equal to about 3 W/mK.

In a related embodiment, the lamp may further include an optic, and the method may further include reflecting at least a portion of the radiation emitted by the at least one LED off a surface of the optic and through the substrate. In another related embodiment, a temperature drop from the junction to the at least one edge may be less than or equal to about 40° C.

### BRIEF DESCRIPTION OF THE DRAWINGS

The foregoing and other objects, features and advantages disclosed herein will be apparent from the following description of particular embodiments disclosed herein, as illustrated in the accompanying drawings in which like reference characters refer to the same parts throughout the different views. The drawings are not necessarily to scale, emphasis instead being placed upon illustrating the principles disclosed herein.

FIG. 1 shows a schematic of an exemplary light transmitting circuit board and conductive traces according to embodiments disclosed herein.

FIG. 2. is a cross-sectional view of the LED and optics structures of an exemplary lamp according to embodiments disclosed herein.

FIGS. 3A and 3B provide cross sectional and perspective views of another exemplary lamp according to embodiments disclosed herein.

FIGS. 4A and 4B provide cross sectional and perspective views of yet another exemplary lamp according to embodiments disclosed herein.

FIGS. 5A and 5B are block flow diagrams of a method according to embodiments disclosed herein.

FIG. 6 is a plot of calculated maximum LED temperature (T) vs. substrate plate thickness for a series of exemplary lamps according to embodiments disclosed herein.

### DETAILED DESCRIPTION

Embodiments as described herein include lamps and luminaires having light sources that include at least one solid state light source, such as but not limited to a light emitting diode (LED), coupled to an optically transmitting, thermally conductive substrate. As such, embodiments contemplate new lamp and luminaire concepts that take advantage of the properties of such a substrate, and which provide desirable lighting characteristics. Of course, such a substrate could also be incorporated into a luminaire having any number of lamps, without departing from the scope of the invention. Additionally, such a substrate (or a plurality of such substrates) could be incorporated into other light-generating devices and apparatus, such as but not limited to backlit displays and the like, without departing from the scope of the invention. Further, at least one of other types of solid state light sources (e.g., OLED(s), PLED(s), etc.) could be used in place of the at least one LED without departing from the scope of the invention. Thus, as used herein, the terms “light emitting diode”, “LED”, and “LED light source” are used interchangeably, and refer to any light emitting diode or other type of carrier injection/junction-based system that is capable of generating radiation in response to an electrical signal. Thus, the term LED includes, but is not limited to, various semiconductor-based structures that emit light in response to current, light emitting polymers, light emitting stripes, electro-luminescent strips, and the like. In particular, the term LED refers to light emitting diodes of all types (including semi-conductor and organic light emitting diodes) that may be configured to generate light in all or various portions of one or more of the visible, ultraviolet, and UV spectrum. Non-limiting examples of suitable LEDs that may be used include various types of infrared LEDs, ultraviolet LEDs, red LEDs, green LEDs, blue LEDs, yellow LEDs, amber LEDs, orange LEDs, and white LEDs. Such LEDs may be configured to emit light over a broad spectrum (e.g., the entire visible light spectrum) or a narrow spectrum.

The LED light sources used in the present disclosure may be formed by one or a plurality of individual LEDs. For example, the LED light source may be configured to include a number of individual LEDs that emit different spectra but which, collectively, emit light that is of a desired color (e.g., white, red, blue, green, yellow, orange, amber, etc.) and/or color temperature. An LED may also be associated with a phosphor that is an integral part of the LED. In some embodiments, The LED light source is a packaged LED chip including one or more packages, each package containing one or more LED chips. Alternatively or additionally, the LED light source may be a bare LED chip, or a plurality of bare LED chips.

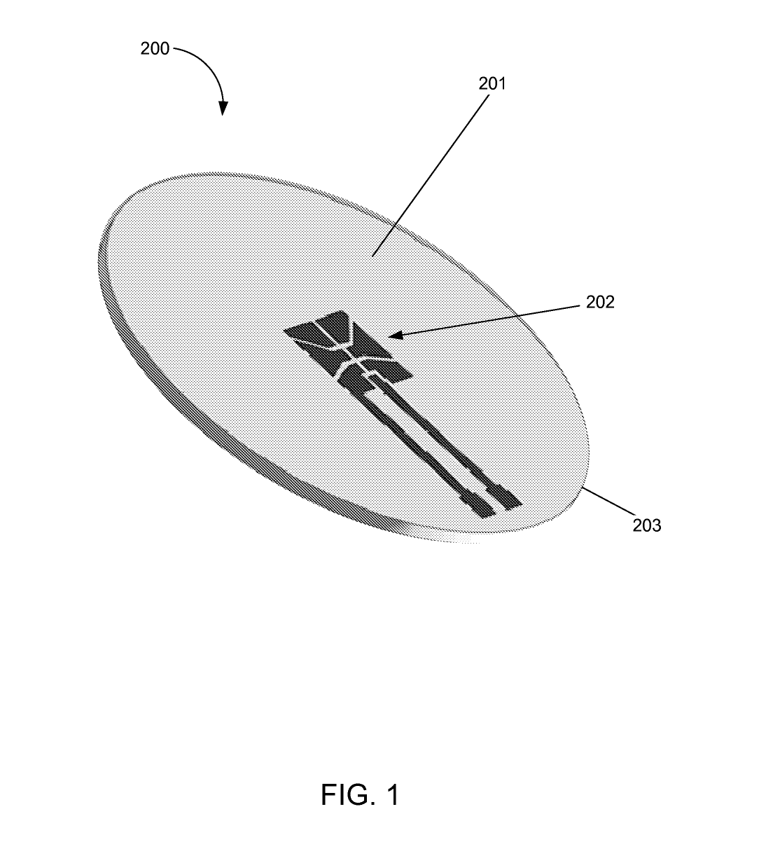

FIG. 1 illustrates a light transmitting circuit board 200. As shown, the light transmitting circuit board 200 includes an optically transmitting, thermally conductive substrate 201 (hereinafter substrate 201) having a first side (not labeled), a second side (not labeled), and at least one edge 203. Conductive traces 202 are deposited on the first side of the substrate 201. As shown, the conductive traces 202 correlate to a footprint for an LED light source that may be coupled to the substrate 202. However, one of ordinary skill in the art will understand that the conductive traces 202 need not define a footprint for an LED, and may be disposed and distributed on the substrate 201 in any desired fashion.

For the purpose of clarity, it should be understood that the term “optically transmitting, thermally conductive substrate” means a substrate that is both an “optically transmitting substrate” as defined below, and a “thermally conductive substrate” as defined below. Furthermore, while FIG. 1 depicts the substrate 201 as having a circular shape, it should be understood that substrate 201 may be, and in some embodiments, is formed in any desired shape, e.g., square, rectangular, oblong, etc.

As used herein, the term “optically transmitting substrate” means a substrate that is capable of transmitting at least a portion of rays that are emitted from at least one LED light source. In some embodiments, the optically transmitting substrates described herein are capable of transmitting greater than 0%, greater than or equal to about 1%, greater than or equal to about 5%, 25%, 50%, 75%, or even greater than or equal to about 95% of rays emitted by at least one LED light source. Of course, substrates that are capable of transmitting more or less rays, or a percentage of rays emitted by at least one LED light source that is/are between any of the aforementioned endpoints are contemplated by the present disclosure. In some embodiments, the rays emitted by the LED light source are in the visible spectrum. However, LED light sources that emit in other regions of the electromagnetic spectrum (e.g., infrared, ultraviolet, etc.) may also be used, and are envisioned by the present disclosure.

As used herein, the term “thermally conductive substrate” refers to a substrate that has sufficient thermal conductivity to conduct heat from a junction of at least one LED light source disposed on the substrate to at least one edge of the substrate. As is understood in the art, thermal conductivity is a material property, often reported in watts per meter Kelvin (W/mK) that is indicative of a material's ability to conduct heat. Heat transfer across materials of high thermal conductivity generally occurs at a faster rate than heat transfer across materials of low thermal conductivity.

In some embodiments, the substrates disclosed herein have a thermal conductivity ranging from greater than or equal to about 3 W/mK, such as about 3.5 to about 400 W/mK, from about 4 to about 350 W/mK, from about 5 to about 300 W/mK, or even from about 10 to about 300 W/mK. For example, some of the substrates described herein have a thermal conductivity of about 40 W/mK. Of course, substrates with thermal conductivities above, below, and within the aforementioned ranges may be used, and are contemplated by the present disclosure.

The thickness of the substrates described herein may have an impact on one or both of the optical transmission and the thermal conductance of the substrate in question. As used herein, the term “thermal conductance” means the quantity of heat transferred by a substrate over a defined unit of time. In general, optical transmission decreases as substrate thickness increases, whereas thermal conductance increases as substrate thickness increases. Similarly, optical transmission typically increases as substrate thickness decreases, whereas thermal conductance decreases as substrate thickness decreases. As a result, it is possible to utilize a wide variety of materials to form the substrates disclosed herein by optimizing thickness in view of the intrinsic optical transmission and thermal conductivity of the material in question. For example, a suitable substrate could be formed from a material with relatively high intrinsic thermal conductivity and relatively low optical transmission, simply by reducing the thickness of the substrate in question. For example, the substrates disclosed herein may have a thickness ranging from greater than 0 to about 10 mm, such as about 0.5 to about 6.5 mm, from about 1 to about 5 mm, or even from about 1 to about 2 mm. Of course, substrates with a thickness greater than, less than, or within any of the aforementioned ranges could also be used, and are envisioned by the present disclosure.

As non-limiting examples of materials that may be utilized to form the substrates described herein, mention is made of AlN, polycrystalline Al₂O₃, BaF₂, BeO, CaF₂, diamond, InGaN, LiF, LiNbO₃, LiTaO₃, NaF, MgF₂, MgO, quartz, sapphire, SiC, Y₂O₃, Y₃Al₅O₁₂, and combinations thereof. In some embodiments, the substrate is formed from polycrystalline Al₂O₃ or sapphire.

In some embodiments, the substrate is configured such that it has a thermal conductivity and thickness sufficient to transfer heat between the junction of the at least one LED light source and at least one edge of the substrate without the temperature drop between the junction and at least one edge (the “Delta T”) exceeding a desired value. For example, the substrate may be configured such that the Delta T value is less than or equal to about 60° C., such as less than or equal to about 50° C., 40° C., 30° C., 20° C., 10° C., or even less than or equal to about 1° C. In some embodiments, the Delta T value is about 40° C. In this regard, Table 1 provides non-limiting examples of substrates having a combination of thermal conductivity and thickness sufficient to transfer heat between a junction of an LED and at least one edge of the substrate with a Delta T value less than or equal to about 40° C., while still being optically transmitting to rays emitted by an LED light source.

TABLE 1

| | Thermal Conductivity | Exemplary Thickness |
|---|---|---|
| Material | (W/mK) | (mm) |
| SiC | 300 | 0.3 |
| BeO | 140 | 0.3 |
| AlN | 140 | 0.3 |
| InGaN | 130 | 0.3 |
| MgO | 60 | 0.5 |
| CaF₂ | 60 | 0.5 |
| Al₂O₃ (sapphire) | 40 | 0.5 |
| Al₂O₃ (polycrystalline) | 30 | 0.8 |
| LiF | 11 | 2.0 |
| MgF₂ | 11.6 | 2.0 |
| BaF₂ | 11.7 | 2.0 |
| Y₂O₃ | 10 | 2.0 |
| Y₃Al₅O₁₂ | 12 | 2.0 |
| Quartz | 9.5 | 2.0 |
| LiNbO₃ | 9.4 | 2.0 |
| LiTaO₃ | 5 | 5.0 |
| NaF | 4 | 6.0 |

Of course, substrates with greater or lesser Delta T values, or Delta T values falling within the above mentioned endpoints may be used, and are envisioned by the present disclosure.

In some embodiments, the substrate is configured as a circuit board. Accordingly, the substrate may include electrical traces, e.g., for the provision of electric power and/or signals to at least one LED light source or other components disposed on the substrate. Such traces may be formed by depositing at least one conductive material on the surface of the substrate. Non-limiting examples of suitable conductive materials include copper, gold, tungsten, tungsten plated with gold, tungsten plated with copper, and other metals. In some embodiments, the traces are formed from tungsten, tungsten plated with gold, or tungsten plated with copper. In instances where the substrate is polycrystalline alumina or sapphire, for example, the traces may be formed from tungsten, which adheres better to alumina and sapphire than copper or gold. All or a portion of the tungsten traces may then be plated with gold or copper to facilitate the connection between the circuit board and electronic components disposed thereon. It should be understood that the traces formed on the circuit board may be of any width necessary to support the provision of electric power or signals to the various components disposed on the substrate. However, because the traces may interfere with the transmission of light through the substrate, it may be desirable to control their width. Accordingly, the present disclosure contemplates optically transmitting, thermally conductive circuit boards with traces having a width of less than or equal to about 2 mm, such as less than or equal to about 1 mm, less than or equal to about 0.5 mm, or even greater than 0 to about 0.5 mm. In some embodiments, the traces are formed from tungsten, and have a width less than or equal to about 1 mm. Of course, wider or narrower traces may be used, as well as traces having a width between any of the aforementioned endpoints. If desired, the traces may further include and/or be plated with at least one of a solder mask or a paint. For example, the traces may be coated with a white paint so as to decrease optical loss caused by the traces.

In addition to serving as a support and/or a circuit board for at least one LED light source, the substrates described herein may also be configured to serve as an optical element in a LED based lamp. For example, the substrate may be configured with a first side (supporting at least one LED) having a first profile, and a second side having a second profile, wherein the first and second cross sectional profiles are the same or different. In some embodiments, the first profile may be flat or substantially flat, and the second profile may be curved (e.g., convex, concave, curvilinear, etc.), and/or faceted. Alternatively, both sides of the substrate may be curved and/or faceted. In addition, the substrates described herein may further include additives, coatings, or other components that impact the transmission of light through the substrate. For example, one or more coatings may be deposited on the substrate. Such coatings may have a refractive index that is the same or different than the refractive index of the substrate. Similarly, particles may be coated onto or dispersed within the substrate or one or more surfaces of the substrate may be roughened, e.g., to enhance diffuse scattering of light that is emitted by the at least one LED source and transmitted through the substrate.

The optically transmitting, thermally conductive circuit boards described herein may be made with a wide variety of techniques. For example, a circuit board may be manufactured by applying a metal containing paste to a finished substrate (e.g., a ceramic substrate such as but not limited to sapphire or polycrystalline alumina) in a circuit pattern, and firing the substrate in a furnace to leave pure metal traces behind. Alternatively, in instances in which a ceramic substrate is used, a circuit board may be formed by applying a metal containing paste to a green-state ceramic substrate, and co-firing the ceramic and paste in a furnace to simultaneously densify the ceramic and leave pure metal traces behind. After the metal traces are deposited, the substrate may undergo further processing as desired, e.g., to deposit copper/gold on the metal traces, to deposit a solder mask, etc. Once the substrate is formed, it may be populated with LED light sources and other components (electrically active or otherwise), as desired.

As noted above, the substrates described herein may take the form of an optically transmitting, thermally conductive circuit board. However, it is emphasized that the substrates may be configured as a support and/or optical element that is not a circuit board. In such embodiments, the substrates may be formed without traces, and electrical power may be provided to the LED light source(s) and other components on the substrate by wires or other separate electrical conductors.

The at least one LED of embodiments described herein may be configured to exhibit a junction temperature (Tj) that is within a desired value. For example, the LEDs disclosed herein may exhibit a junction temperature less than or equal to about 150° C., such as less than or equal to about 130° C., 125° C., 115° C., 100° C., 90° C., 80° C., 70° C., 60° C., 50° C., 40° C., 30° C., or even less than or equal to about 25° C. In some embodiments, the LEDs described herein are configured to have a junction temperature less than or equal to about 125° C. Of course, Tj values above, below, and between any of the aforementioned endpoints may be used, and are envisioned by the present disclosure.

In some embodiments, the substrates described herein may function to conduct heat from a junction of at least one LED light source to at least one edge. For example, the substrates described herein may function to remove heat from the base of an LED light source, and conduct that heat to another location, such as the edge of the substrate, a lamp body, a heat sink, and/or another heat dissipating structure. By removing heat in this manner, the substrates disclosed herein may maintain the junction temperature of an LED light source at or below a desired value, such as the Tj values discussed above. In some embodiments, the substrates have sufficient thermal conductivity and thickness to perform this function with a relatively low Delta T, as described above. For example, the substrates described herein may have a thickness and thermal conductivity sufficient to maintain Tj at or below about 125° C., and to conduct heat from the junction to at least one edge of the substrate with a Delta T of less than or equal to about 40° C. In this regard, reference is made to Table 1, which discloses various exemplary materials having a combination of thermal conductivity and thickness to conduct heat from a junction of at least one LED to an edge of the substrate with a Delta T less than or equal to about 40° C.

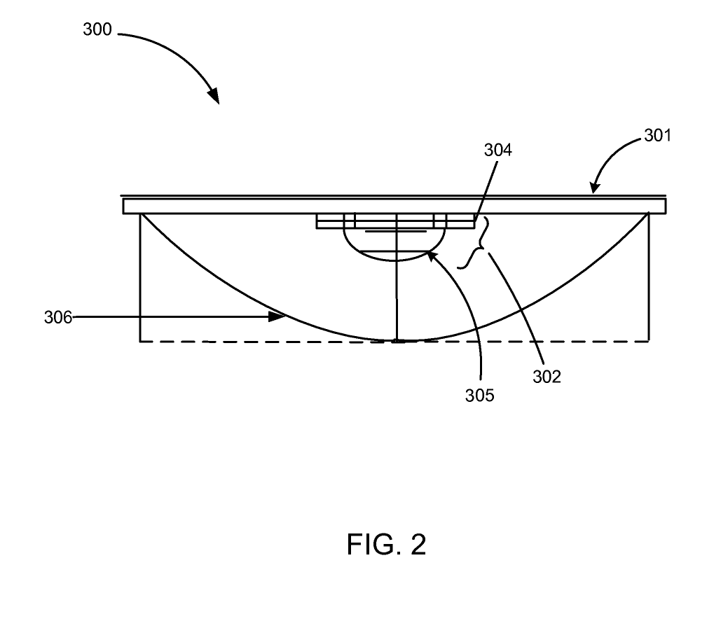

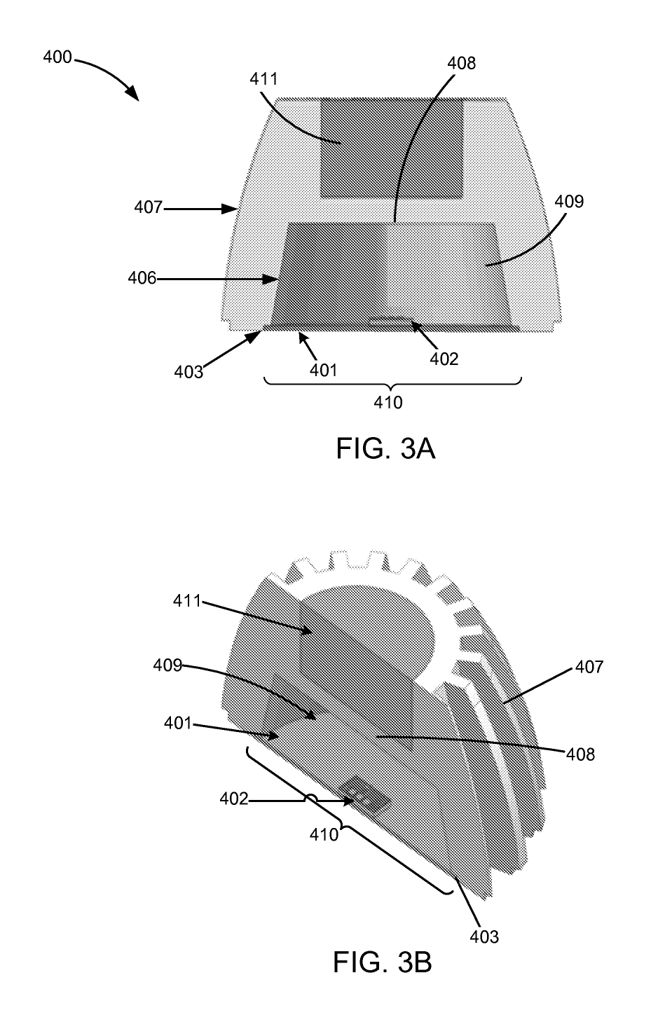

LED's as used in embodiments described herein may be of any structure suitable for use in a lamp. As a non-limiting example of one LED configuration that may be used, reference is made to FIG. 2, which provides a cross sectional view of a lamp 300 including an LED light source 302. As shown the LED light source includes for example, a submount 304, LED circuitry (not labeled) on the submount 304, and a dome 305 (or other optic) disposed about the LED circuitry and at least a portion of the submount 304. The position of the LED light source on the substrates disclosed herein may be selected to achieve a desired optical effect, and/or a desired level of light transmission through the substrate. For example, and as shown in FIG. 3, the LED light source 302 may be positioned on a first surface of the substrate 301, such that it faces inward to the base of the lamp or, in this case, the base of an optic such as a reflector 306. Orienting the LED light source 302 in this manner may enhance the probability that rays emitted from the LED light source 302 will impinge on the reflector 306.

While the LED light source 302 may be physically positioned at any location along a first side of the substrate 301, it may be desirable to position the LED light source 302 in or about the aperture of the lamp or an optic such as a reflector, as shown in FIG. 3 For example, in instances where the reflector 306 is configured as a parabolic reflector (as in FIG. 3), the LED light source 302 may be positioned in or near the center of the aperture of the parabolic reflector 306, so that all or nearly all of the rays emitted by the LED light source 302 impinge on the parabolic reflector 306. Such an optical configuration may allow a tightly collimated beam to be formed in a relatively small amount of space (e.g., cubic inches of optics volume). Indeed, since all or nearly all of the rays hit the reflector 306, it is possible to achieve maximum collimation. Moreover, light reflected by the reflector 306 may pass through the substrate 301 with little optical loss and/or scattering.

To exemplify this principle, the approximate maximum optic diameter, optics diameter, approximate optics depth for minimum full width half maximum (FWHM), and approximate system FWHM were calculated based on three lamp types utilizing six different LED types. The calculations assumed that a parabolic reflector was used as the optic. The results are reported in Table 2 below.

TABLE 2

| | | | | | | Approx. | |
|---|---|---|---|---|---|---|---|
| | | | | | | Optics | |
| | | Approx. | | Approx. | | Depth | Approx. |
| | | LED | | Max. | | for | System |
| | | Emitter | Emitter | Optics | Optics | Min. | Min. |
| Lamp | LED | Diameter | FWHM | Diameter | Diameter | FWHM | FWHM |
| Type | Type | (mm) | (°) | (1/8″) | (mm) | (mm) | (°) |
| MR16 | OSTAR | 4.2 | 140 | 14 | 44 | 11 | 10 |
| | Lighting Plus | | | | | | |
| MR16 | OSLON 150 | 2 | 150 | 14 | 44 | 11 | 5 |
| MR16 | OSLON 80 | 2 | 80 | 14 | 44 | 11 | 3 |
| MR16 | 10 mm dia. | 10 | 120 | 14 | 44 | 11 | 22 |
| | emitter | | | | | | |
| MR16 | 15 mm dia. | 15 | 120 | 14 | 44 | 11 | 34 |
| | emitter | | | | | | |
| MR16 | 20 mm dia. | 20 | 120 | 14 | 44 | 11 | 46 |
| | emitter | | | | | | |
| PAR30 | OSTAR | 4.2 | 140 | 28 | 89 | 22 | 5 |
| | Lighting Plus | | | | | | |
| PAR30 | OSLON 150 | 2 | 150 | 28 | 89 | 22 | 2 |
| PAR30 | OSLON 80 | 2 | 80 | 28 | 89 | 22 | 2 |
| PAR30 | 10 mm dia. | 10 | 120 | 28 | 89 | 22 | 11 |
| | emitter | | | | | | |
| PAR30 | 15 mm dia. | 15 | 120 | 28 | 89 | 22 | 17 |
| | emitter | | | | | | |
| PAR30 | 20 mm dia. | 20 | 120 | 28 | 89 | 22 | 22 |
| | emitter | | | | | | |
| PAR38 | OSTAR | 4.2 | 140 | 36 | 114 | 29 | 4 |
| | Lighting Plus | | | | | | |
| PAR38 | OSLON 150 | 2 | 150 | 36 | 114 | 29 | 2 |
| PAR38 | OSLON 80 | 2 | 80 | 36 | 114 | 29 | 1 |
| PAR38 | 10 mm dia. | 10 | 120 | 36 | 114 | 29 | 9 |
| | emitter | | | | | | |
| PAR38 | 15 mm dia. | 15 | 120 | 36 | 114 | 29 | 13 |
| | emitter | | | | | | |
| PAR38 | 20 mm dia. | 20 | 120 | 36 | 114 | 29 | 17 |
| | emitter | | | | | | |

In Table 2, the LED emitter diameter was estimated from datasheet drawings and is the effective emitter size for calculating the minimum system FWHM (etendue) calculations. The emitter FWHM is the directional radiation intensity FWHM of the LED in question. The approximate maximum optics diameter is an approximated value, and equates to the lamp diameter minus one quarter (0.25) inch. The number of each lamp corresponds to the lamp diameter measured in one eighth (0.125) inches. The approximate optics depth is the optics diameter divided by 4. This assumes that the optic is a parabolic reflector and that the LED is located at the focus of the parabola for increased collimation and decreased minimum system FWHM. It should be noted that the reflectors described in this specification need not be parabolic, and that the LED light sources need not be placed at the focus of a parabolic reflector. By way of example, a faceted reflector may be used, which may improve beam quality by hiding LED source artifacts in the far field. Moreover, moving the LED light source from the focus may allow for a larger system FWHM, which may be desirable in some lighting applications. By way of example, common reflector lamp FWHM's range from about 8° to about 80°.

The approximate system FWHM in Table 2 was calculated using the optical principal of etendue: sin θ_{system}=(emitter diameter/optics diameter)*sin θₑₘᵢₜₜₑᵣ, where 2θ=FWHM, under the assumption that the LED and reflector were immersed in air (n=1). One of ordinary skill will understand that this is a fundamental physical limit. FWHM may be increased by having a non-parabolic reflector, not having the LED positioned at the focus of the reflector, adding a diffuser to the lamp, etc. However, FWHM cannot be made smaller. It should also be noted that FWHM may be impacted by the material forming the substrates described herein. For example, polycrystalline alumina may add about 10 to about 20° to the system FWHM for thicknesses of about 1 mm.

While FIG. 2 is described above as including a reflector 306, it is emphasized that a variety of optics may be used in the lamps of the present disclosure. As non-limiting examples of such optics, mention is made of parabolic reflectors, faceted reflectors, reflectors using total internal reflection, lenses, lens systems, light pipes, fiber optics, and the like.

The basic structures discussed above and shown in FIGS. 1 and 2 may be incorporated into a LED-based lighting system, such as a narrow beam angle spotlight. In this regard, reference is made to FIGS. 3A and 3B, which provide cross sectional and perspective views of a lamp 400 according to embodiments disclosed herein. As shown, the lamp 400 includes a lamp body 407 having a first cavity for driving electronics 411, and a second cavity 409. The second cavity 409 is substantially defined by a base (not labeled), an opening 410 substantially opposite to the base, and opposing sides of the lamp body 407 or an optic disposed within the second cavity 409 (later described). An LED light source 402 is disposed on a first side of an optically transmitting, thermally conductive substrate 401, and mounted at or near the opening 410 of the lamp body 407 such that it substantially faces the base of the second cavity 409. The substrate 401 is secured to the lamp body (or a separate heat sink), e.g., by a mechanical fastener, snap-fit, or an adhesive. While the LED light source 402 is positioned in FIGS. 3A and 3B substantially in the center of the opening 410, it should be noted that it may be positioned at any other location along the substrate 401 and/or within the second cavity 409, as described above.

In FIGS. 3A and 3B, the walls and base of the lamp body 407 facing the second cavity 409 may be formed as an optic, e.g., as a reflector, a lens, or other equivalent optical device. This may be accomplished, for example, by forming the lamp body of an intrinsically reflecting material, by coating or depositing a reflecting material on the relevant portions of the second cavity 409, or through another mechanism. Alternatively or additionally, an optic such as those previously described may be disposed within the second cavity 409.

During operation of lamp 400, the LED light source 402 emits rays generally in a direction towards the base and walls of the second cavity 409, or an optic disposed within the second cavity 409. When the rays impinge upon these structures, at least a portion are redirected (e.g., reflected) so as to impinge upon the first side of the substrate 401. Because the substrate 401 is optically transmitting, at least a portion of the rays are transmitted through the substrate 401 and are emitted from the lamp. As the LED light source 402 operates, it emits heat from at least one junction. To support the longevity of the LED light source 402, this heat is conducted by the substrate 401 from the at least one junction to at least one edge of the substrate 401. At or near the edge of substrate 401, the conducted heat is transferred to another portion of the lamp 400 or radiated into the surrounding space. For example, the lamp body 407 may be configured as a heat sink for receiving and dissipating heat that is conducted by the substrate 401 away from the LED junction. Alternatively or additionally, the lamp 400 may include one or more heat sinks configured to receive and dissipate heat that is conducted away from the LED junction by the substrate 401, either independently of or in conjunction with the lamp body 407. To facilitate the transfer of heat from the substrate 401 to the lamp body 407 and/or a separate heat sink, the substrate 401 may be coupled to the lamp body 407 and/or a heat sink by a thermal transfer medium, such as but not limited to a thermal paste. For example, the outer perimeter of the substrates disclosed herein may be in contact with a thermal interface material, which in turn is in contact with the lamp body and/or the heat sink.

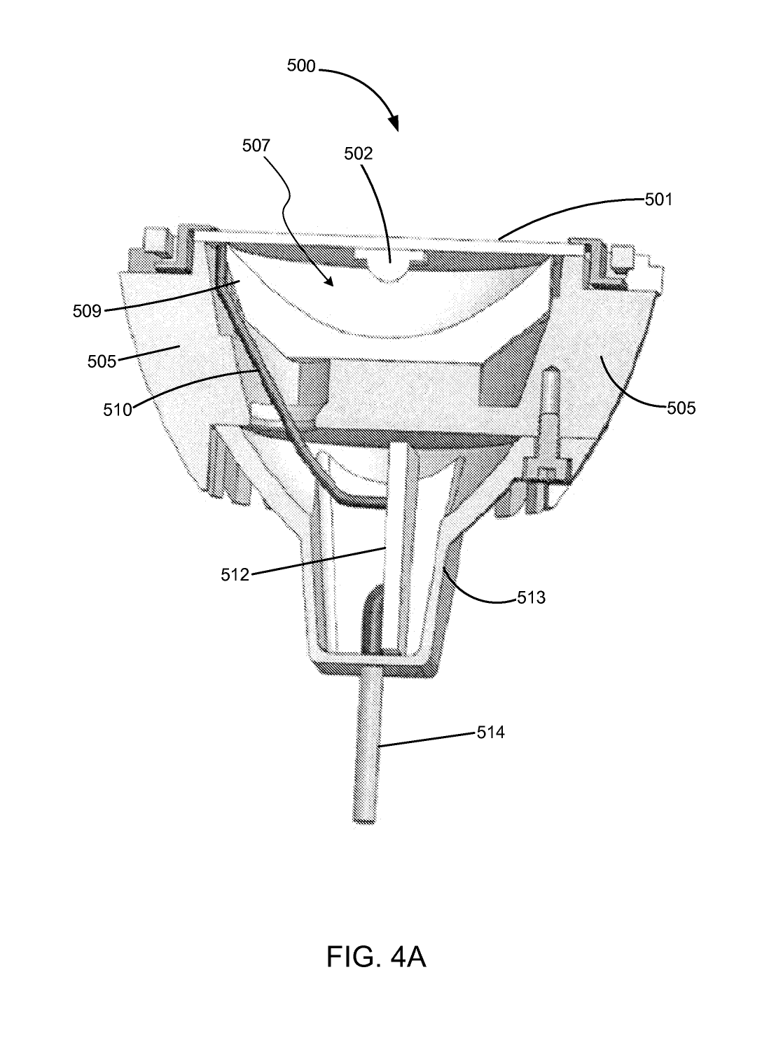

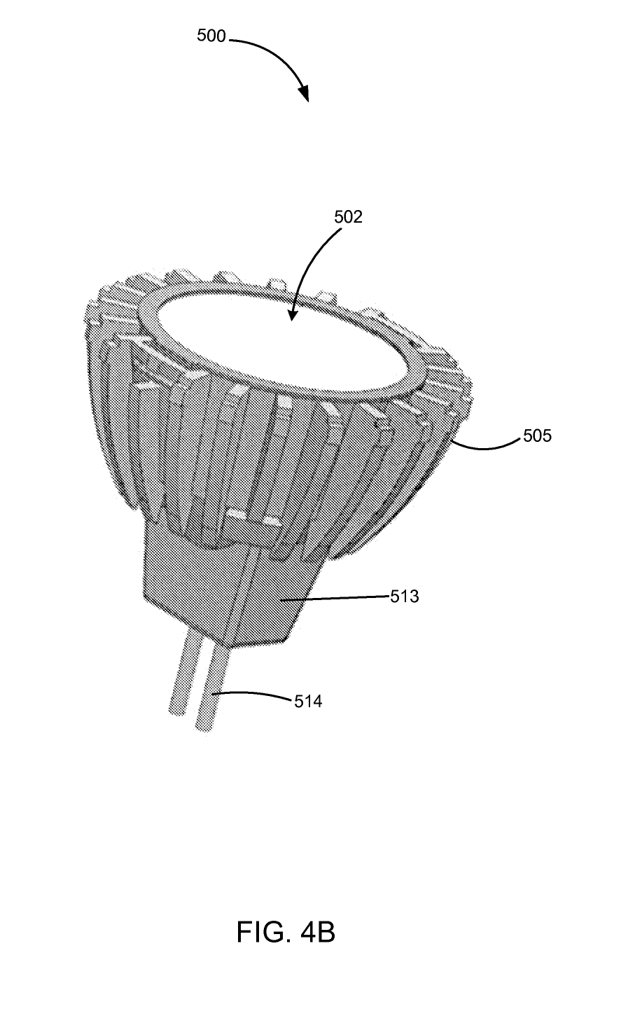

FIGS. 4A and 4B provide internal cross-section and outside perspective views of other non-limiting lamps according to the present disclosure. As shown, the lamp 500 includes an optically transmitting, thermally conductive substrate 501 coupled to a heat sink (lamp body) 505, e.g., with a ring shaped thermal interface material (not shown). The substrate 501 is secured to the heat sink 505 via a fastening means, such as a mechanical fastener (e.g., a screw, a nut, a bolt), snap fit, and or an adhesive. The heat sink 505 defines a cavity 507 having a base (not labeled) and an opening substantially opposite the base. The substrate 501 is disposed substantially within the opening of the cavity 507. An LED light source 502 is disposed on a first surface of the substrate 501 such that it faces or substantially faces the base of the cavity 507. A parabolic reflector 509 is disposed between the base of the cavity 507 and the LED light source 502. A driver housing 513 is coupled to the heat sink 505, e.g., via a fastening means such as described above. An electronic driver 512 is disposed within the driver housing 513, and is connected to the substrate 501 via an electrical connector 510. In addition, the electronic driver 512 is connected to an external power source (not shown) via a pin base 514, which is disposed through the base of the driver housing 513. Of course, other base connector configurations (e.g., a screw base) may also be used to connect the electronic driver 512 to an external power source, and are envisioned by the present disclosure. As depicted in FIG. 4B, the lamp 500 may be configured to have a particular shape of similar lamps that include a thermal bridge, but of course the lamp 500 lacks such a thermal bridge.

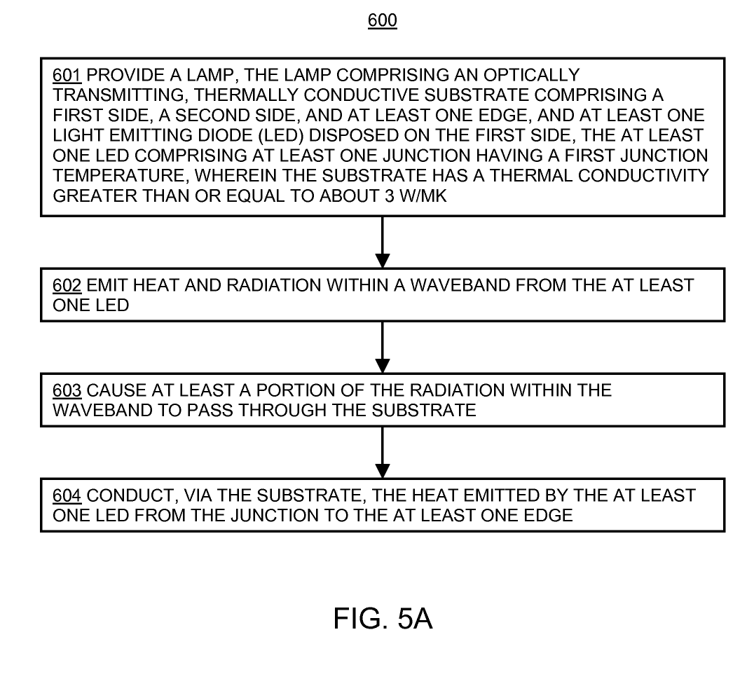

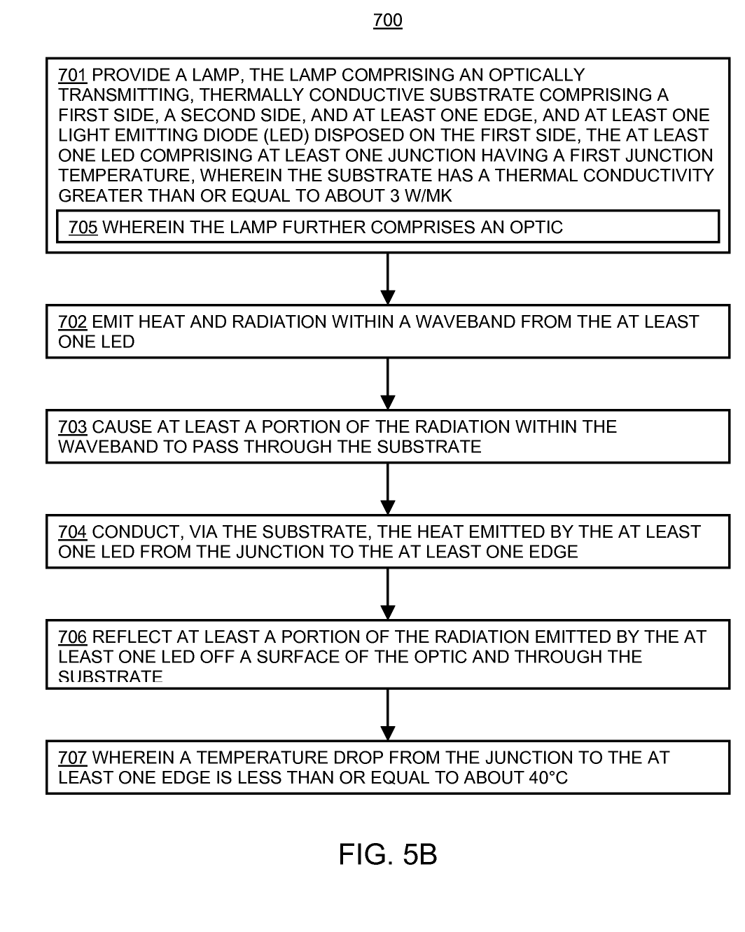

FIGS. 5A-5B are flowcharts of methods 600 and 700, as described herein. The flowcharts illustrate the functional information one of ordinary skill in the art requires to perform operations in accordance with the present invention. It will be appreciated by those of ordinary skill in the art that unless otherwise indicated herein, the particular sequence of steps described is illustrative only and may be varied without departing from the spirit of the invention. Thus, unless otherwise stated, the steps described below are unordered, meaning that, when possible, the steps may be performed in any convenient or desirable order.

More particularly, FIGS. 5A and 5B show methods 600 and 700, respectively. A lamp is provided, step 601/701. The lamp comprises an optically transmitting, thermally conductive substrate comprising a first side, a second side, and at least one edge, as described herein. The lamp also includes at least one light emitting diode (LED) disposed on the first side, the at least one LED comprising at least one junction having a first junction temperature. The substrate has a thermal conductivity greater than or equal to about 3 W/mK.

Heat and radiation are emitted within a waveband from the at least one LED, step 602/702. At least a portion of the radiation within the waveband is caused to pass through the substrate, step 603/703. The heat emitted by the at least one LED is conducted, via the substrate, from the junction to the at least one edge, step 604/704.

In some embodiments, the lamp further comprises an optic, step 705. In such embodiments, the method 700 further comprises reflecting at least a portion of the radiation emitted by the at least one LED off a surface of the optic and through the substrate, step 706. In some embodiments, the method 700 also includes wherein a temperature drop from the junction to the at least one edge is less than or equal to about 40° C., step 707.

To investigate and develop various lamps according to embodiments described herein, various optical and thermal lamp simulations were run, non-limiting examples of which are described below.

### Example 1

### MR16 Lamp with LED Facing into the Reflector

In this example, optical simulations were run using a theoretical MR16 lamp design based on a parabolic reflector and an LED disposed on an optically transmitting, thermally conductive sapphire substrate (n=1.78). The LED package consisted of a square array of four 1×1 mm LED chips immersed in a 5.6 mm diameter silicone dome on a 6.6 mm square ceramic submount and having an optical output of 500 lumens. The ceramic submount had a reflectivity (R) of 70%, with lambertian scattering of reflected light. The parabolic reflector was assumed to be specular with R=90% to replicate a high quality aluminum coating. No scatter was included in the simulation for the sapphire plate, but real polycrystalline alumina would be expected to have thickness dependent scatter. The reflector was parabolic in profile with a diameter of 30 mm and reflector cup depth optimized for maximum collimation, up to a maximum value of 15 mm.

Five million rays were traced, and a cup depth of 8.2 mm was found to have maximum collimation for the 30 mm diameter reflector. The ratio of cup diameter to depth was close to the theoretical value of 4 for maximum collimation for a point source located at the focus of a parabolic reflector. The calculated CBCP was 4000cd, despite the narrow beam angle (FWHM) of 13-15°. The calculated optical efficiency was 75.7%, with much of the optical loss due to rays striking the LED package and being absorbed after reflecting from the parabolic reflector.

### Example 2

### MR16 with Wide Angle LED Facing into the Reflector

Further optical simulations were run using a theoretical lamp having substantially the same construction as the lamp in Example 1, except that the LED utilized a dome lens having a radius of curvature of 4.0 mm was used. The diameter of the dome lens remained at 5.6 mm. One goal of these simulations was to use a wider than lambertian beam distribution from the LED source, with fewer reflected rays striking the LED.

Five million rays were traced, and a cup depth of 8.1 mm was determined to maximize collimation for the 30 mm cup diameter. The calculated beam angle (FWHM) was 15° and calculated CBCP was ˜4500cd, 10-20% higher than the hemispherical dome. The calculated optical efficiency was 67.4%, about 10% lower than the hemispherical dome. The decrease in efficiency was due to fewer rays initially exiting the LED dome. Despite the decreased efficiency, CBCP was significantly increased, which may be desirable for applications requiring a high CBCP.

### Example 3

### PAR38 Lamp with LED Facing into the Reflector

Further optical simulations were run using a theoretical lamp having substantially the same construction as the lamp in Example 1, except that the optics diameter was increased to 90 mm, which is suitable for a PAR38 size lamp. A reflector depth of 19 mm was found to yield maximum collimation. The calculated CBCP and optical efficiency of the PAR38 lamp were about 20,000cd and 87%, respectively. The larger reflector size with the same LED leads to a significant enhancement in optical efficiency due to fewer reflected rays striking the LED source.

### Example 4

### Lamp Thermal Simulations

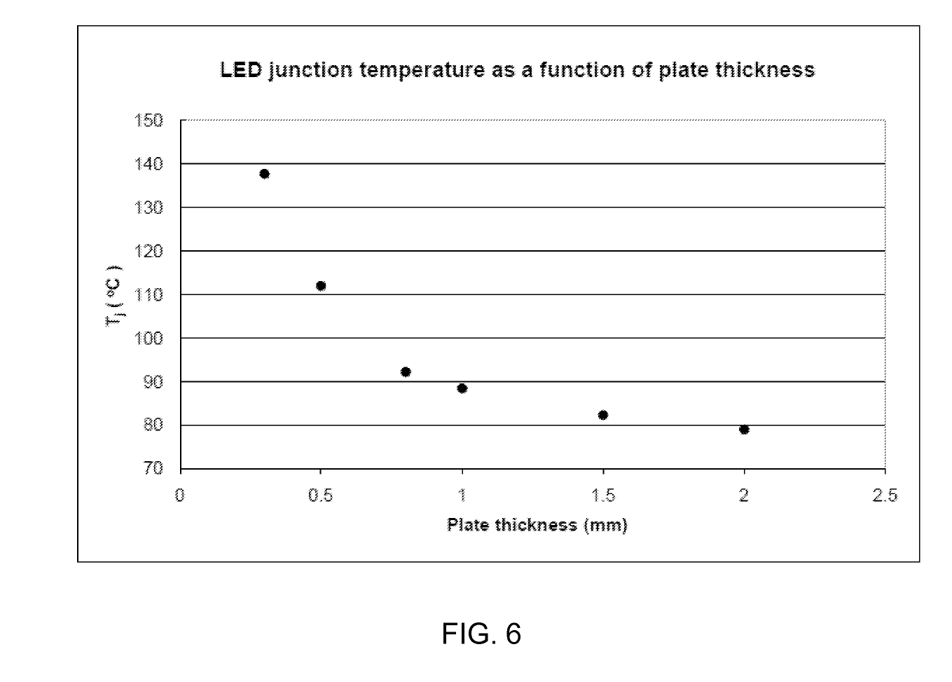

To evaluate the impact of thickness on the effectiveness of an optically transparent, thermally conductive substrate's ability to conduct heat from the junction of an LED light source to at least one edge of the substrate, thermal simulations were run using a common lamp configuration with varying substrate thickness. The simulations assumed the use of an MR16 style lamp, and a 4.5 W, 500 lumen LED source disposed on a polycrystalline alumina substrate. The substrate thickness was varied from about 0.3 to about 2.0 mm, and the maximum LED temperature (Tmax) was calculated. The results are shown in FIG. 6. As shown, the calculated Tmax depended strongly on the thickness of the substrate. The lamps employing a 0.3 mm thick substrate exhibited a calculated Tmax of ˜137° C. In contrast, the lamps using a 2.0 mm thick substrate exhibited a calculated Tmax of ˜79° C. Of note is the fact that the calculated Tmax of the 2.0 mm thick polycrystalline alumina substrate was only about 8° C. higher than the Tmax of a 2 mm thick metal core printed circuit board.

Other than in the examples, or where otherwise indicated, all numbers expressing endpoints of ranges, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present disclosure. At the very least, and not as an attempt to limit the application of the doctrine of equivalents to the scope of the claims, each numerical parameter should be construed in light of the number of significant digits and ordinary rounding approaches.

Notwithstanding that the numerical ranges and parameters setting forth the broad scope of the present disclosure are approximations, unless otherwise indicated the numerical values set forth in the specific examples are reported as precisely as possible. Any numerical value, however, inherently contains certain errors necessarily resulting from the standard deviation found in their respective testing measurements.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein.

Although the methods and systems have been described relative to a specific embodiment thereof, they are not so limited. Obviously many modifications and variations may become apparent in light of the above teachings. Many additional changes in the details, materials, and arrangement of parts, herein described and illustrated, may be made by those skilled in the art.

What is claimed is:

1. An apparatus comprising:
a substrate having a first side, a second side, and at least one edge; and
at least one light emitting diode (LED) disposed on the first side, the at least one LED comprising at least one junction having a first junction temperature; wherein the substrate is an optically transmitting, thermally conductive substrate and the substrate has a thermal conductivity greater than or equal to about 3 W/mK.

2. The apparatus of claim 1, wherein the substrate is configured such that the temperature drop between the at least one junction and the at least one edge is less than or equal to about 40° C.

3. The apparatus of claim 1, wherein the substrate has a thickness ranging from about 0.1 mm to about 6 mm.

4. The apparatus of claim 3, wherein the substrate comprises at least one material selected from the group consisting of AlN, polycrystalline Al₂O₃, BaF₂, BeO, CaF₂, InGaN, LiF, LiNbO₃, LiTaO₃, NaF, MgF₂, MgO, quartz, sapphire, SiC, Y₂O₃, Y₃Al₅O₁₂, and ZrO₂.

5. The apparatus of claim 1, wherein the substrate has a thermal conductivity ranging from about 3.5 to about 400 W/mK.

6. The apparatus of claim 1, wherein the first junction temperature is less than or equal to about 125° C.

7. The apparatus of claim 1, further comprising an optic, wherein the first side of the substrate faces the optic.

8. The apparatus of claim 7, wherein the optic comprises an aperture, and the substrate and the at least one LED are disposed at or within the aperture.

9. The apparatus of claim 7, wherein the optic comprises a reflector.

10. The apparatus of claim 1, further comprising a heat sink, the heat sink comprising a base, an opening positioned substantially opposite to the base, and a cavity therebetween, wherein the substrate is disposed within the cavity or across the opening such that the first side of the substrate faces the base.

11. The apparatus of claim 10, wherein the substrate conducts heat from the at least one junction to the heat sink, and is configured such that the temperature drop between the at least one junction and the heat sink is less than or equal to about 40° C.

12. An apparatus, comprising:
a heat sink having a base, an opening, and a cavity therebetween;
an optically transmitting, thermally conductive substrate supported within the cavity or across the opening, the substrate comprising a first side, a second side, and at least one edge, the first side facing the base;
at least one light emitting diode (LED) disposed on the first side of the substrate, the at least one LED comprising at least one junction having a first junction temperature;
wherein the substrate has a thermal conductivity greater than or equal to about 3 W/mK.

13. The apparatus of claim 12, further comprising an optic positioned within the cavity and between the at least one LED and the base.

14. The apparatus of claim 13, wherein the at least one LED emits rays, and at least a portion of the rays are reflected by the optic through the substrate.

15. The apparatus of claim 12, wherein said substrate is configured to conduct heat produced by the at least one LED to the heat sink, the substrate being configured such that the temperature drop between said at least one junction and said heat sink is less than or equal to about 40° C.

16. The apparatus of claim 12, wherein the first junction temperature is less than or equal to about 125° C.

17. The apparatus of claim 12, wherein the substrate has a thermal conductivity ranging from about 3.5 to about 400 W/mK.

18. A method, comprising:
providing a lamp, the lamp comprising:
an optically transmitting, thermally conductive substrate comprising a first side, a second side, and at least one edge; and
at least one light emitting diode (LED) disposed on the first side, the at least one LED comprising at least one junction having a first junction temperature;
emitting heat and radiation within a waveband from the at least one LED;
causing at least a portion of the radiation within the waveband to pass through the substrate; and
conducting, via the substrate, the heat emitted by the at least one LED from the junction to the at least one edge;
wherein the substrate has a thermal conductivity greater than or equal to about 3 W/mK.

19. The method of claim 18, wherein the lamp further comprises an optic, and wherein the method further comprises reflecting at least a portion of the radiation emitted by the at least one LED off a surface of the optic and through the substrate.

20. The method of claim 18, wherein a temperature drop from the junction to the at least one edge is less than or equal to about 40° C.
